(19) United States
(12) Patent Application Publication
(10) Pub. No.: US 2008/0164595 A1
(43) Pub. Date: Jul. 10, 2008

(54) STACKABLE SEMICONDUCTOR PACKAGE AND THE METHOD FOR MAKING THE SAME

(75) Inventors: Yen-Yi Wu, Kaoshiung (TW); Pao-Huei Chang Chien, Kaohsiung (TW); Wei-Yueh Sung, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: ADVANCED SEMICONDUCTOR ENGINEERING, INC., Kaohsiung (TW)

(21) Appl. No.: 11/968,846

(22) Filed: Jan. 3, 2008

(30) Foreign Application Priority Data
Jan. 9, 2007 (TW) 096100817

(51) Int. Cl. H01L 23/12; H01L 21/60

(52) U.S. Cl. 257/686; 438/109; 257/E21.511; 257/E21.508; 257/E23.003

(57) ABSTRACT

The present invention relates to a stackable semiconductor package and the method for making the same. The stackable semiconductor package comprises a first substrate, a semiconductor device, a plurality of stud bumps, a plurality of first wires, a second substrate, and a molding compound. The semiconductor device is disposed on the first substrate and electrically connected to the first substrate. The stud bumps are above the semiconductor device. The first wires are used for electrically connecting the stud bumps and the first substrate. The stud bumps are in contact with the second substrate. The molding compound encapsulates the first substrate, the semiconductor device, the stud bumps, the first wires, and the second substrate, and thus, the second substrate will not undergo wire bonding, and will not be suspended and shake or sway, as present in a conventional stackable semiconductor package.

### BACKGROUND OF THE INVENTION

1. Field of the Invention

The present invention relates to a stackable semiconductor package, and more particularly to a stackable semiconductor package using stud bumps to support a substrate.

2. Description of the Related Art

FIG. 1 shows a schematic cross-sectional view of a conventional stackable semiconductor package. The conventional stackable semiconductor package 1 comprises a first substrate 11, a chip 12, a second substrate 13, a plurality of wires 14 and a molding compound 15. The first substrate 11 has a first surface 111 and a second surface 112. The chip 12 is attached to the first surface 111 of the first substrate 11 by flip-chip bonding. The second substrate 13 is adhered to the chip 12 through an adhesive layer 16. The second substrate 13 has a first surface 131 and a second surface 132, and the first surface 131 has a plurality of first bonding pads 133 and a plurality of second bonding pads 134. Viewed from the top, the area of the second substrate 13 is larger than that of the chip 12, so that some portions of the second substrate 13 extend out of the chip 12, so as to form a suspended portion.

The wires 14 electrically connect the first bonding pads 133 of the second substrate 13 to the first surface 111 of the first substrate 11. The molding compound 15 encapsulates the first surface 111 of the first substrate 11, the chip 12, the wires 14, and a portion of the second substrate 13, and exposes the second bonding pads 134 on the first surface 131 of the second substrate 13, thus forming a mold area opening 17. Generally, another package 18 or other devices can be further stacked in the mold area opening 17 of the conventional stackable semiconductor package 1, in which solder balls 181 of the package 18 are electrically connected to the second bonding pads 134 of the second substrate 13.

The conventional stackable semiconductor package 1 has the following disadvantages. First, as the second substrate 13 has a suspended portion, the first bonding pads 133 are disposed on the periphery relative to the chip 12 (i.e., the suspended portion), and the distance between the first bonding pads 133 and the position relative to the edge of the chip 12 is defined as a span length. According to experiments, when the span length is more than three times greater than the thickness of the second substrate 13, the suspended portion may shake or sway during the wire bonding process, which will affect the wire bonding operation. Further, during the wire bonding process, under an extremely high downward pressure, the second substrate 13 might crack. Moreover, to avoid the aforementioned circumstances of swaying, shaking, and cracking, the suspended portion cannot be too long, and thus the area of the second substrate 13 is limited, so the layout space of the second bonding pads 134 on the first surface 131 of the second substrate 13 that is exposed by the mold area opening 17 will be restricted. Also, during molding, the molding compound 15 may overflow between an upper mold (not shown) and the first surface 131 of the second substrate 13 to form flash, which will contaminate the second bonding pads 134.

Therefore, it is necessary to provide an innovative and advanced stackable semiconductor package to solve the above problems.

### SUMMARY OF THE INVENTION

The present invention is mainly directed to a stackable semiconductor package, which comprises a first substrate, a semiconductor device, a plurality of stud bumps, a plurality of first wires, a second substrate, and a molding compound. The first substrate has a first surface and a second surface. The semiconductor device is disposed on the first surface of the first substrate, and electrically connected to the first surface of the first substrate. The stud bumps are disposed above the semiconductor device. The first wires are used for electrically connecting the stud bumps and the first surface of the first substrate. The second substrate has a first surface and a second surface. The stud bumps are in contact with the second surface of the second substrate. The molding compound encapsulates the first surface of the first substrate, the semiconductor device, the stud bumps, the first wires, and the second surface of the second substrate.

In the present invention, the second substrate will not undergo wire bonding, and thus will not be suspended and shake or sway as in a conventional package. Further, during the molding process of the molding compound, the molding compound will not overflow between the upper mold and the first surface of the second substrate, thus preventing the first bonding pads from being contaminated. Also, the upper surface of the stackable semiconductor package (i.e., the first surface of the second substrate) is an extremely flat surface, and more packages or other devices, or larger ones, can be disposed thereon.

The present invention is further directed to a method for making the stackable semiconductor package which comprises the following steps:

(a) providing a first substrate having a first surface and a second surface;

(b) attaching a semiconductor device to the first surface of the first substrate, the semiconductor device being electrically connected to the first surface of the first substrate;

(c) forming a plurality of stud bumps above the semiconductor device;

(d) forming a plurality of first wires for electrically connecting the stud bumps and the first surface of the first substrate;

(e) providing a second substrate having a first surface and a second surface;

(f) disposing the second substrate on the stud bumps, so that the stud bumps are in contact with the second surface of the second substrate; and

(g) encapsulating the first surface of the first substrate, the semiconductor device, the stud bumps, the first wires, and the second surface of the second substrate in a molding compound.

### BRIEF DESCRIPTION OF THE DRAWINGS

FIG. 1 is a schematic cross-sectional view of a conventional stackable semiconductor package;

FIG. 2 is a schematic cross-sectional view of a stackable semiconductor package according to a first embodiment of the present invention;

FIG. 3 is a flow chart of a method for making the stackable semiconductor package according to the first embodiment of the present invention;

FIG. 4 is a schematic cross-sectional view of a stackable semiconductor package according to a second embodiment of the present invention;

FIG. 5 is a flow chart of a method for making the stackable semiconductor package according to the second embodiment of the present invention; and

FIG. 6 is a schematic cross-sectional view of a stackable semiconductor package according to a third embodiment of the present invention.

### DETAILED DESCRIPTION OF THE INVENTION

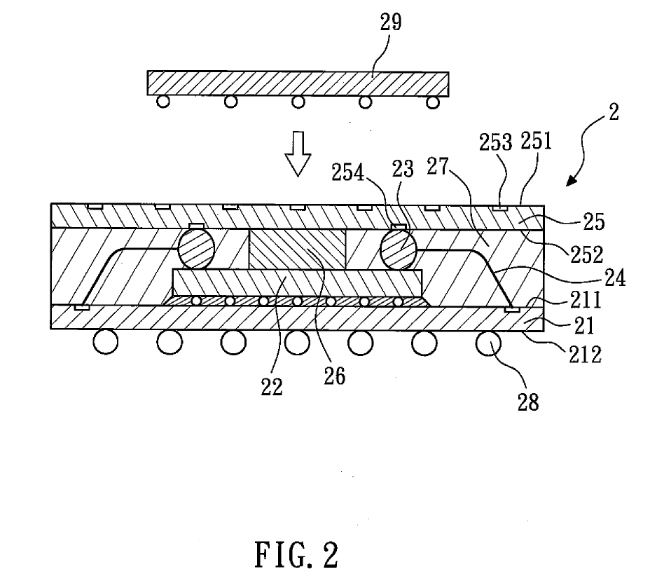

FIG. 2 shows a schematic cross-sectional view of a stackable semiconductor package according to a first embodiment of the present invention. The stackable semiconductor package 2 comprises a first substrate 21, a semiconductor device 22, a plurality of stud bumps 23, a plurality of first wires 24, a second substrate 25, a support compound 26, a molding compound 27, and a plurality of solder balls 28.

The first substrate 21 has a first surface 211 and a second surface 212. The semiconductor device 22 is disposed on the first surface 211 of the first substrate 21, and electrically connected to the first surface 211 of the first substrate 21. In this embodiment, the semiconductor device 22 is a chip, and is attached to the first surface 211 of the first substrate 21 by flip-chip bonding.

The stud bumps 23 (for example, gold stud bumps) are disposed above the semiconductor device 22. In this embodiment, the stud bumps 23 are disposed on a top surface of the semiconductor device 22. The first wires 24 connect the stud bumps 23 and the first surface 211 of the first substrate 21.

The second substrate 25 has a first surface 251 and a second surface 252. The first surface 251 of the second substrate 25 has a plurality of first bonding pads 253, and the second surface 252 of the second substrate 25 has a plurality of second bonding pads 254. The stud bumps 23 are electrically connected to and in contact with the second bonding pads 254 on the second surface 252 of the second substrate 25. The stud bumps 23 are used for supporting the second substrate 25, and transmitting a signal from the second substrate 25 to the first substrate 21 through the first wires 24.

The support compound 26 is disposed between the top surface of the semiconductor device 22 and the second surface 252 of the second substrate 25 in order to enhance the support to the second substrate 25. The molding compound 27 encapsulates the first surface 211 of the first substrate 21, the semiconductor device 22, the stud bumps 23, the first wires 24, the second surface 252 of the second substrate 25, and the support compound 26. The solder balls 28 are disposed on the second surface 212 of the first substrate 21.

Generally, in the stackable semiconductor package 2, another package 29 or other devices can be further stacked on the first surface 251 of the second substrate 25, and electrically connected to the first bonding pads 253 on the first surface 251 of the second substrate 25.

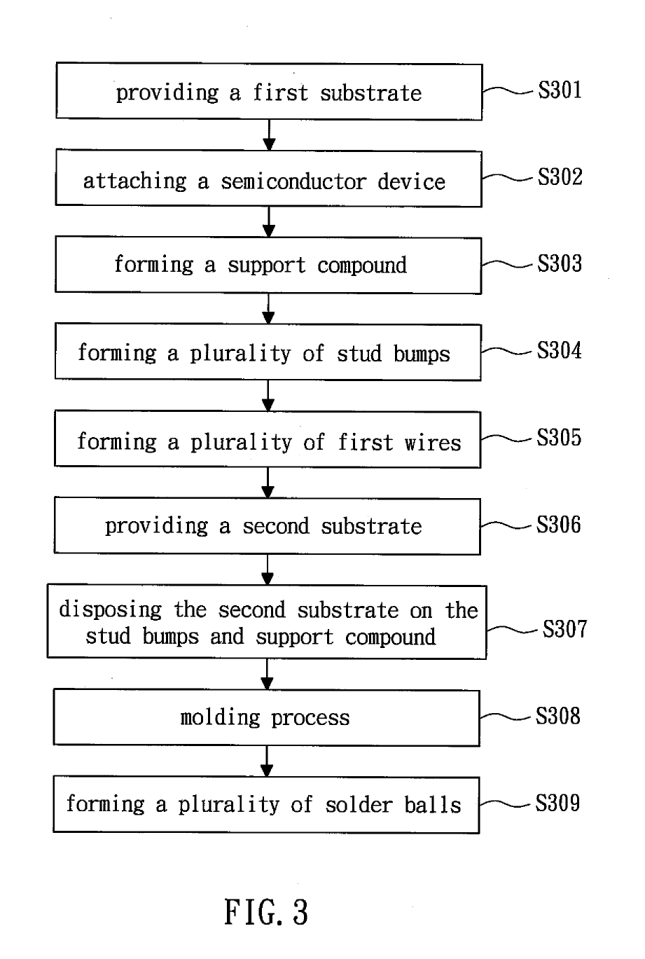

FIG. 3 shows a flow chart of a method for making the stackable semiconductor package according to the first embodiment of the present invention. Referring to FIG. 2, a method for making the stackable semiconductor package 2 comprises the following steps. In Step S301, a first substrate 21 having a first surface 211 and a second surface 212 is provided. In Step S302, a semiconductor device 22 is attached to the first surface 211 of the first substrate 21, and is electrically connected to the first surface 211 of the first substrate 21. In this embodiment, the semiconductor device 22 is a chip, and is attached to the first surface 211 of the first substrate 21 by flip-chip bonding.

In Step S303, a support compound 26 is formed above the semiconductor device 22. In this embodiment, the support compound 26 is directly formed on and adhered to the top surface of the semiconductor device 22. It should be noted that this step is optional. In Step S304, a plurality of stud bumps 23 (for example, gold stud bumps) is formed above the semiconductor device 22. In this embodiment, the stud bumps 23 are directly formed on and attached to the top surface of the semiconductor device 22.

In Step S305, a plurality of first wires 24 is formed to electrically connect the stud bumps 23 and the first surface 211 of the first substrate 21. In Step S306, a second substrate 25 having a first surface 251 and a second surface 252 is provided. In Step S307, the second substrate 25 is disposed on the stud bumps 23 and the support compound 26, so that the stud bumps 23 and the support compound 26 are in contact with and support the second surface 252 of the second substrate 25.

In Step S308, a molding process is performed in which a molding compound 27 is used to encapsulate the first surface 211 of the first substrate 21, the semiconductor device 22, the stud bumps 23, the first wires 24, the support compound 26, and the second surface 252 of the second substrate 25. In Step S309, a plurality of solder balls 28 is formed on the second surface 212 of the first substrate 21, so as to form the stackable semiconductor package 2.

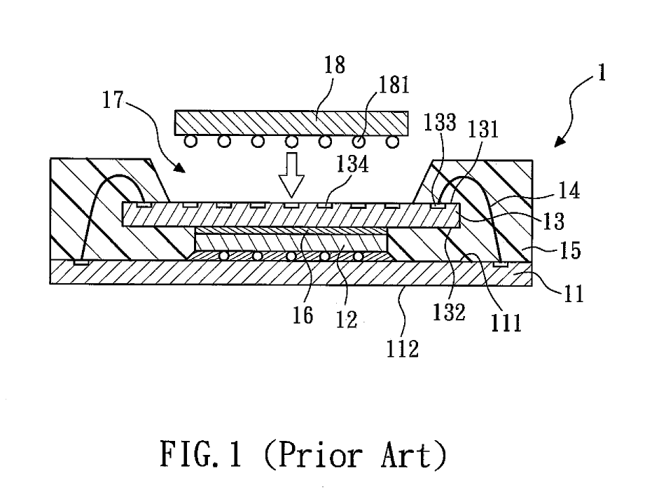

In the present invention, the second substrate 25 will not undergo wire bonding, and will not be suspended and shake or sway like the second substrate 13 in the conventional package 1 (FIG. 1). Moreover, during the molding process of the molding compound 27, the molding compound 27 will not overflow between the upper mold (not shown) and the first surface 251 of the second substrate 25, thus preventing the first bonding pads 253 from being contaminated. Further, the upper surface of the stackable semiconductor package 2 (i.e., the first surface 251 of the second substrate 25) is an extremely flat surface, and more packages 29 or other devices, or larger ones, can be disposed thereon.

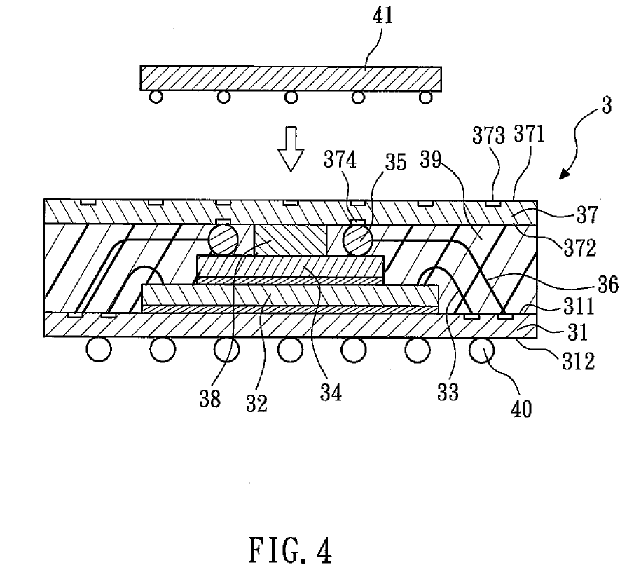

FIG. 4 shows a schematic cross-sectional view of a stackable semiconductor package according to a second embodiment of the present invention. The stackable semiconductor package 3 comprises a first substrate 31, a semiconductor device 32, a plurality of second wires 33, an intermediate device 34, a plurality of stud bumps 35, a plurality of first wires 36, a second substrate 37, a support compound 38, a molding compound 39, and a plurality of solder balls 40.

The first substrate 31 has a first surface 311 and a second surface 312. The semiconductor device 32 is disposed on the first surface 311 of the first substrate 31, and electrically connected to the first surface 311 of the first substrate 31. In this embodiment, the semiconductor device 32 is a first chip. The semiconductor device 32 is adhered to the first surface 311 of the first substrate 31, and is electrically connected to the first surface 311 of the first substrate 31 through the second wires 33.

The intermediate device 34 is adhered to the semiconductor device 32. The intermediate device 34 may be a spacer without electrical functions, or another chip with electrical functions.

The stud bumps 35 (for example, gold stud bumps) are disposed above the semiconductor device 32. In this embodiment, the stud bumps 35 are disposed on a top surface of the intermediate device 34. The first wires 36 electrically connect the stud bumps 35 and the first surface 311 of the first substrate 31.

The second substrate 37 has a first surface 371 and a second surface 372. The first surface 371 of the second substrate 37 has a plurality of first bonding pads 373, and the second surface 372 of the second substrate 37 has a plurality of second bonding pads 374. The stud bumps 35 are connected to and in contact with the second bonding pads 374 on the second surface 372 of the second substrate 37. The stud bumps 35 are used for supporting the second substrate 37, and transmitting a signal from the second substrate 37 to the first substrate 31 through the first wires 35.

The support compound 38 is disposed between the top surface of the intermediate device 34 and the second surface 372 of the second substrate 37 in order to enhance the support to the second substrate 37. The molding compound 39 encapsulates the first surface 311 of the first substrate 31, the semiconductor device 32, the second wires 33, the intermediate device 34, the stud bumps 35, the first wires 36, the second surface 372 of the second substrate 37, and the support compound 38. The solder balls 40 are disposed on the second surface 312 of the first substrate 31.

Generally, in the stackable semiconductor package 3, another package 41 or other devices can be further stacked on the first surface 371 of the second substrate 37, and electrically connected to the first bonding pads 373 on the first surface 371 of the second substrate 37.

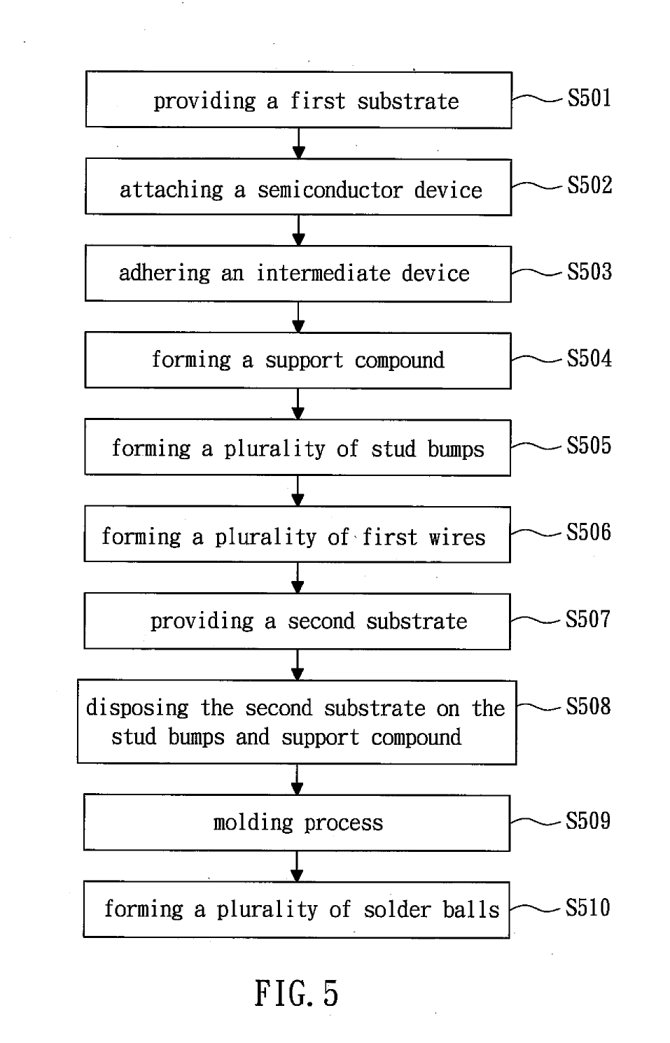

FIG. 5 shows a flow chart of a method for making the stackable semiconductor package according to the second embodiment of the present invention. Referring to FIG. 4, a method for making the stackable semiconductor package 3 comprises the following steps. In Step S501, a first substrate 31 having a first surface 311 and a second surface 312 is provided. In Step S502, a semiconductor device 32 is attached to the first surface 311 of the first substrate 31, and is electrically connected to the first surface 311 of the first substrate 31. In this embodiment, the semiconductor device 32 is a first chip. The semiconductor device 32 is adhered to the first surface 311 of the first substrate 31, and is electrically connected to the first surface 311 of the first substrate 31 through the second wires 33.

In Step S503, an intermediate device 34 is adhered to a top surface of the semiconductor device 32. The intermediate device 34 may be a spacer without electrical functions, or another chip with electrical functions.

In Step S504, a support compound 38 is formed above the semiconductor device 32. In this embodiment, the support compound 38 is directly formed on and adhered to the top surface of the intermediate device 34. It should be noted that this step is optional. In Step S505, a plurality of stud bumps 35 (for example, gold stud bumps) is formed above the semiconductor device 32. In this embodiment, the stud bumps 35 are directly formed on and attached to the top surface of the intermediate device 34.

In Step S506, a plurality of first wires 36 is formed to electrically connect the stud bumps 35 and the first surface 311 of the first substrate 31. In Step S507, a second substrate 37 having a first surface 371 and a second surface 372 is provided. In Step S508, the second substrate 37 is disposed on the stud bumps 35 and the support compound 38, so that the stud bumps 35 and the support compound 38 are in contact with and support the second surface 372 of the second substrate 37.

In Step S509, a molding process is performed in which a molding compound 39 is used to encapsulate the first surface 311 of the first substrate 31, the semiconductor device 32, the second wires 33, the intermediate device 34, the stud bumps 35, the first wires 36, the second surface 372 of the second substrate 37, and the support compound 38. In Step S510, a plurality of solder balls 40 is formed on the second surface 312 of the first substrate 31, so as to form the stackable semiconductor package 3.

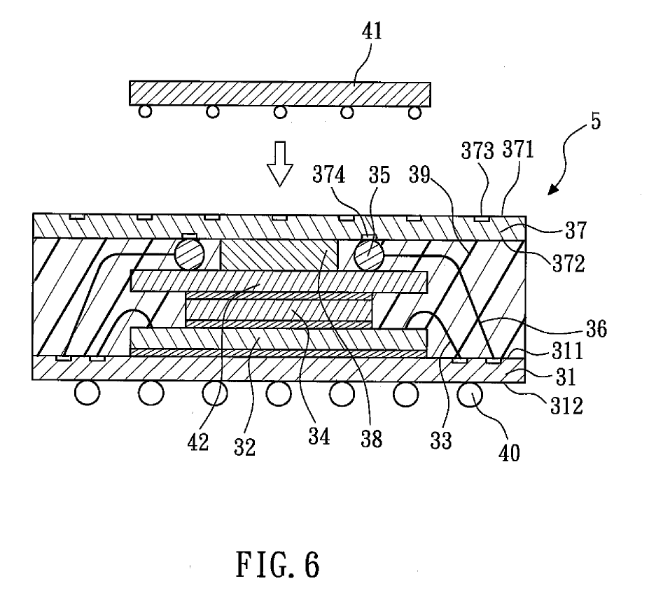

FIG. 6 shows a schematic cross-sectional view of a stackable semiconductor package according to a third embodiment of the present invention. The difference between the stackable semiconductor package 5 and the stackable semiconductor package 3 of the second embodiment (as shown in FIG. 4) is that the stackable semiconductor package 5 has a second chip 42 adhered to the intermediate device 34, and the support compound 38 and the stud bumps 35 are disposed on a top surface of the second chip 42. Moreover, in this embodiment, the intermediate device 34 is a spacer without signal functions.

The difference between the method for making the stackable semiconductor package 5 and the method for making the stackable semiconductor package 3 of the second embodiment (as shown in FIG. 5) is that, after Step S503 in FIG. 5, a second chip 42 is further adhered to the intermediate device 34. Also, in Step S504, the support compound 38 is directly formed on and adhered to the top surface of the second chip 42, and in Step S505, the stud bumps 35 are directly formed on and attached to the top surface of the second chip 42.

While several embodiments of the present invention have been illustrated and described, various modifications and improvements can be made by those skilled in the art. The embodiments of the present invention are therefore described in an illustrative but not restrictive sense. It is intended that the present invention should not be limited to the particular forms as illustrated, and that all modifications which maintain the spirit and scope of the present invention are within the scope defined in the appended claims.

What is claimed is:

1. A stackable semiconductor package, comprising:
a first substrate, having a first surface and a second surface;
a semiconductor device, disposed on the first surface of the first substrate, and electrically connected to the first surface of the first substrate;
a plurality of stud bumps, disposed above the semiconductor device;
a plurality of first wires, electrically connecting the stud bumps and the first surface of the first substrate;
a second substrate, having a first surface and a second surface, wherein the stud bumps are in contact with the second surface of the second substrate; and
a molding compound, encapsulating the first surface of the first substrate, the semiconductor device, the stud bumps, the first wires, and the second surface of the second substrate.

2. The stackable semiconductor package as claimed in claim 1, wherein the semiconductor device is a chip, the semiconductor device is attached to the first surface of the first substrate by flip-chip bonding, and the stud bumps are disposed on the chip.

3. The stackable semiconductor package as claimed in claim 1, further comprising an intermediate device, wherein the semiconductor device is a first chip, the semiconductor device is adhered to the first surface of the first substrate and is electrically connected to the first surface of the first substrate through a plurality of second wires, the intermediate device is adhered to the semiconductor device, and the stud bumps are disposed on the intermediate device.

4. The stackable semiconductor package as claimed in claim 3, wherein the intermediate device is a spacer without electrical functions.

5. The stackable semiconductor package as claimed in claim 3, wherein the intermediate device is another chip.

6. The stackable semiconductor package as claimed in claim 1, further comprising a spacer and a second chip, wherein the semiconductor device is a first chip, the semiconductor device is adhered to the first surface of the first substrate and is electrically connected to the first surface of the first substrate through a plurality of second wires, the spacer is adhered to the semiconductor device, the second chip is adhered to the spacer, and the stud bumps are disposed on the second chip.

7. The stackable semiconductor package as claimed in claim 1, wherein the stud bumps are gold stud bumps.

8. The stackable semiconductor package as claimed in claim 1, wherein the first surface of the second substrate has a plurality of first bonding pads, the second surface of the second substrate has a plurality of second bonding pads, and the stud bumps are connected to the second bonding pads.

9. The stackable semiconductor package as claimed in claim 1, further comprising a plurality of solder balls, disposed on the second surface of the first substrate.

10. The stackable semiconductor package as claimed in claim 1, further comprising a support compound, disposed on the second surface of the second substrate.

11. A method for making a stackable semiconductor package, comprising the steps of:
(a) providing a first substrate having a first surface and a second surface;
(b) attaching a semiconductor device to the first surface of the first substrate, the semiconductor device being electrically connected to the first surface of the first substrate;
(c) forming a plurality of stud bumps above the semiconductor device;
(d) forming a plurality of first wires for electrically connecting the stud bumps and the first surface of the first substrate;
(e) providing a second substrate having a first surface and a second surface;
(f) disposing the second substrate on the stud bumps, so that the stud bumps are in contact with the second surface of the second substrate; and
(g) encapsulating the first surface of the first substrate, the semiconductor device, the stud bumps, the first wires, and the second surface of the second substrate in a molding compound.

12. The method as claimed in claim 11, wherein in Step (b), the semiconductor device is a chip, and the semiconductor device is attached to the first surface of the first substrate by flip-chip bonding, and in Step (c), the stud bumps are formed on the semiconductor device.

13. The method as claimed in claim 11, wherein in Step (b), the semiconductor device is a first chip, and the semiconductor device is adhered to the first surface of the first substrate and is electrically connected to the first surface of the first substrate through a plurality of second wires.

14. The method as claimed in claim 13, wherein after Step (b), the method further comprises a step of adhering an intermediate device to the semiconductor device, and in Step (c), the stud bumps are formed on the intermediate device.

15. The method as claimed in claim 14, wherein the intermediate device is a spacer without electrical functions.

16. The method as claimed in claim 14, wherein the intermediate device is another chip.

17. The method as claimed in claim 13, wherein after Step (b), the method further comprises a step of adhering a spacer to the semiconductor device, and a step of adhering a second chip to the spacer; and in Step (c), the stud bumps are formed on the second chip.

18. The method as claimed in claim 11, wherein after Step (b), the method further comprises a step of forming a support compound above the semiconductor device.

19. The method as claimed in claim 11, wherein after Step (g), the method further comprises a step of forming a plurality of solder balls on the second surface of the first substrate.
